(19) United States
(12) Patent Application Publication
(10) Pub. No.: US 2018/0277755 A1
(43) Pub. Date: Sep. 27, 2018

(54) NAND-TYPE FINFET DIELECTRIC RRAM

(71) Applicants: SEMICONDUCTOR MANUFACTURING INTERNATIONALA (SHANGHAI) CORPORATION, Shanghai (CN); SEMICONDUCTOR MANUFACTURING INTERNATIONAL (BEIJING) CORPORATION, Beijing (CN)

(72) Inventors: ZHUOFAN CHEN, Shanghai (CN); PANPAN LIU, Shanghai (CN)

(21) Appl. No.: 15/908,706

(22) Filed: Feb. 28, 2018

(30) Foreign Application Priority Data
Mar. 23, 2017 (CN) 201710175979.X

(51) Int. Cl. H01L 45/00; H01L 27/24

(52) U.S. Cl. CPC H01L 45/10; H01L 27/2463; H01L 29/785; H01L 45/1675; H01L 45/1206

(57) ABSTRACT

A semiconductor device includes one or more bit lines, first and second select gates on the one or more bit lines, a plurality of word lines on the one or more bit lines and between the first and second select gates, and a source and a plurality of drains on the one or more bit lines. The source is disposed at an outside of the first select gate, and the plurality of drains are disposed at an outside of the second select gate. The semiconductor device based on electron tunneling effects includes only the source, drains and contacts disposed outside of the first and second select gates, without having a source, drain and contacts on opposite sides of each select gate, thereby increasing the memory density and the speed of write and erase operations.

### CROSS-REFERENCES TO RELATED APPLICATIONS

The present application claims priority to Chinese patent application No. 201710175979.X, filed with the State Intellectual Property Office of People's Republic of China on Mar. 23, 2017, the content of which is incorporated herein by reference in its entirety.

### TECHNICAL FIELD

The present invention relates to semiconductor technology, and more particularly to a resistive random access memory device, a semiconductor device including the resistive random access memory device, and a method for manufacturing thereof.

### BACKGROUND OF THE INVENTION

A memory device can be a complementary metal oxide semiconductor (CMOS) fin-type or NOR-type resistive memory device. A conventional resistive random access memory (RRAM) device is generally fabricated using existing post-processing techniques while a NOR-type RRAM device is fabricated using pre-process techniques.

However, the NOR-type memory utilizes a hot-electron injection write mode, so that each gate requires a drain to be the electron source, that is, a source, a drain, and contacts are required to be disposed on opposite sides of each gate, resulting in low storage density and slow write and erase operations.

### BRIEF SUMMARY OF THE INVENTION

The inventors of the present disclosure discovered the above-described problems and provide a novel technical solution to solve these problems.

According to an aspect of the present disclosure, a semiconductor device includes one or more bit lines, first and second select gates on the one or more bit lines, a plurality of word lines on the one or more bit lines and between the first and second select gates, and a source and a plurality of drains on the one or more bit lines, wherein the source is disposed at an outside of the first select gate and the plurality of drains are disposed at an outside of the second select gate.

In one embodiment, positions of two of the plurality of drains on two adjacent bit lines are shifted from each other along a direction of the one or more bit lines.

In one embodiment, the semiconductor device further includes contacts on the source, the drains, and on the first and second select gates.

According to another aspect of the present disclosure, a method for manufacturing a semiconductor device. The method may include providing a substrate, sequentially forming s shallow trench isolation (STI) layer, a fin layer, a dielectric layer, and a dummy gate layer on the substrate, defining positions of a plurality of word lines on the dummy gate layer, defining positions of first and second select gates on opposite sides of the plurality of word lines, forming a source at an outside of the position of the first select gate and a drain at an outside of the position of the second select gate on the fin layer, and forming first and second select gates on the positions of the first and second select gates and a plurality of word lines on the positions of the plurality of word lines on the dummy gate layer.

In one embodiment, the method may further include forming contacts on the source and the drain.

In one embodiment, the dummy gate layer includes polysilicon, the fin layer includes monocrystalline silicon, and the STI layer includes SiO₂.

In one embodiment, defining the positions of the plurality of word lines on the dummy gate layer includes forming a plurality of cores spaced from each other with an equal distance on the dummy gate layer and having a same cross-sectional width, forming a spacer layer on the plurality of cores to from a trench between two adjacent cores, the trench having a cross-sectional width equal to the cross-sectional width of the cores, etching the spacer layer to expose the cores and the dummy gate layer, and removing the cores to form a plurality of spacers spaced from each other with an equal distance, each of the plurality of spacers defining a position of the word lines.

In one embodiment, the cores include amorphous carbon, and the spacer layer includes silicon nitride or silicon oxide.

In one embodiment, defining the positions of the first and second select gates on opposite sides of the plurality of word lines includes forming a mask on opposite sides of a region where the spacers are disposed, the mask being disposed at a position defining the positions of the first and second select gates, and etching the dummy gate layer into a pattern corresponding to the positions of the word lines and the first and second select gates.

In one embodiment, forming the source at the outside of the position of the first select gate and the drain at the outside of the position of the second select gate on the fin layer includes forming trenches on outer sides of the positions of the first and second select gates on the fin layer, and forming the source and the drain on the respective trenches.

In one embodiment, the source and the drain each include silicon phosphide or silicon carbide, the source and the drain each include an upper surface that is flush with an upper surface of the dielectric layer.

In one embodiment, forming the first and second select gates and the plurality of word lines on the dummy gate layer includes forming an interlayer dielectric layer on the dielectric layer, planarizing the interlayer dielectric layer, removing the dummy gate layer in the interlayer dielectric layer to form corresponding trenches, and forming a metal in the trenches to form the first and second select gates and the plurality of word lines.

Embodiments of the present disclosure also provide a memory device that includes the above-described semiconductor device.

The following detailed description together with the accompanying drawings will provide a better understanding of the nature and advantages of the present invention.

### BRIEF DESCRIPTION OF THE DRAWINGS

Embodiments of the present invention are described with reference to the accompanying drawings. In the drawings, like reference numbers may indicate identical or functionally similar elements.

FIG. 1 is a plan view illustrating a structure diagram of a semiconductor device according to one embodiment of the present disclosure.

FIG. 2 is a simplified flowchart illustrating an example method for manufacturing a semiconductor device according to one embodiment of the present disclosure.

FIG. 3A is a cross-sectional view illustrating an STI layer, a fin layer, a dielectric layer, and a dummy gate layer on a substrate in a semiconductor device manufacturing method according to one embodiment of the present disclosure.

FIG. 3B is a cross-sectional view illustrating a formed spacer in a semiconductor device manufacturing method according to one embodiment of the present disclosure.

FIG. 3C is a cross-sectional view illustrating a determination of word lines (WL) and select gates (SG) positions in a semiconductor device manufacturing method according to one embodiment of the present disclosure.

FIG. 3D is a cross-sectional view illustrating a formed source in a semiconductor device manufacturing method according to one embodiment of the present disclosure.

FIG. 3E is a cross-sectional view illustrating the formation of word lines (WL) and select gates (SG) in a semiconductor device manufacturing method according to one embodiment of the present disclosure.

FIG. 3F is a cross-sectional view illustrating a formed contact (CT) in a semiconductor device manufacturing method according to one embodiment of the present disclosure.

FIG. 4 is a simplified flowchart illustrating an example method of defining position of word lines (WL) and select gates (SG) according to one embodiment of the present disclosure.

FIG. 5A is a cross-sectional view illustrating a formed core in a semiconductor device manufacturing method according to one embodiment of the present disclosure.

FIG. 5B is a cross-sectional view illustrating a formed recess in a semiconductor device manufacturing method according to one embodiment of the present disclosure.

FIG. 5C is a cross-sectional view illustrating a formed select gate (SG) position mask in a semiconductor device manufacturing method according to one embodiment of the present disclosure.

FIG. 6 is a simplified flowchart illustrating an example method for forming a source and a drain of a semiconductor device according to one embodiment of the present disclosure.

FIG. 7A is a cross-sectional view illustrating a formed recess mask in a semiconductor device manufacturing method according to one embodiment of the present disclosure.

FIG. 7B is a cross-sectional view illustrating a formed recess in a semiconductor device manufacturing method according to one embodiment of the present disclosure.

FIG. 8 is a simplified flowchart illustrating an example method for forming select gates (SG) and a word lines (WL) of a semiconductor device according to one embodiment of the present disclosure.

FIG. 9A is a cross-sectional view illustrating an interlayer dielectric layer (ILD) layer formation in a semiconductor device manufacturing method according to one embodiment of the present disclosure.

FIG. 9B is a cross-sectional view illustrating a air gap formation in a semiconductor device manufacturing method according to one embodiment of the present disclosure.

FIG. 10 is a cross-sectional view illustrating a void formation in a semiconductor device manufacturing method according to one embodiment of the present disclosure.

### DETAILED DESCRIPTION OF THE INVENTION

Embodiments of the present invention now will be described more fully hereinafter with reference to the accompanying drawings. The invention may, however, be embodied in many different forms and should not be construed as limited to the embodiments set forth herein. Rather, these embodiments are provided so that this disclosure will be thorough and complete, and will fully convey the scope of the invention to those skilled in the art. The features may not be drawn to scale, some details may be exaggerated relative to other elements for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

The terminology used herein is for the purpose of describing particular embodiments only and is not intended to be limiting of the invention. As used herein, the singular forms “a”, “an”, and “the” are intended to include the plural forms as well, unless the context clearly indicates otherwise. It will be further understood that the terms “comprises”, “comprising”, “includes”, and/or “including” when used herein, specify the presence of stated features, integers, steps, operations, elements, and/or components, but do not preclude the presence or addition of one or more other features, integers, steps, operations, elements, components, and/or groups thereof.

Embodiments of the present invention now will be described more fully hereinafter with reference to the accompanying drawings, in which embodiments of the invention are shown. This invention may, however, be embodied in many different forms and should not be construed as limited to the embodiments set forth herein.

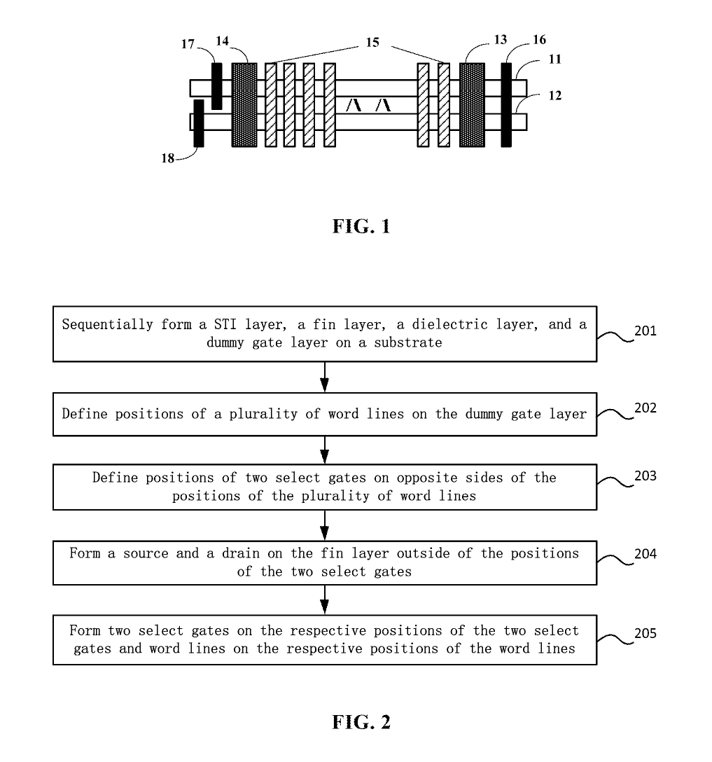

FIG. 1 is a plan view illustrating a structure diagram of a semiconductor device according to one embodiment of the present disclosure.

Referring to FIG. 1, the semiconductor device includes bit lines 11, 12, select gates 13, 14, a plurality of word lines 15, a source 16, and drains 17 and 18.

Select gates 13 and 14 are disposed on adjacent bit lines 11 and 12. Word lines 15 are disposed between select gates 13 and 14. Source 16 is disposed outside of select gate 13. Drains 17 and 18 are disposed outside of select gate 14.

In one embodiment, drain 17 is disposed on bit line 11, drain 18 is disposed on bit line 12, and drains 17 and 18 are shifted from each other along the direction of the bit lines.

In another embodiment, select gates 13 and 14, source 16, drains 17 and 18 each include a contact.

In the embodiment, the NAND-type structure based on electron tunneling effects only includes a source, a drain and contacts disposed outside of the two select gates, without having a source, a drain and contacts disposed on opposite sides of each select gate, thereby increasing the memory density and the speed of write and erase operations.

FIG. 2 is a simplified flowchart illustrating an example method for manufacturing a semiconductor device according to one embodiment of the present disclosure.

Referring to FIG. 2, the method includes:

At 201: sequentially forming a shallow trench isolation (STI) layer, a fin layer, a dielectric layer, and a dummy gate layer on a substrate.

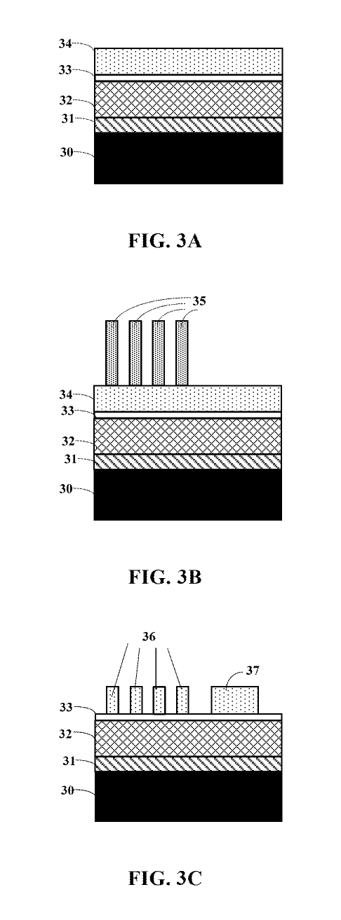

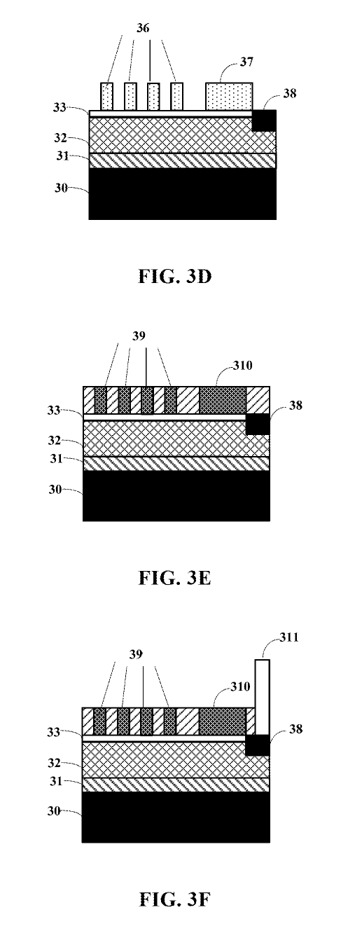

In one embodiment, referring to FIG. 3A, a STI layer 31, a fin layer 32, a dielectric layer 33, and a dummy gate layer 34 are sequentially formed on a substrate 30 using a chemical vapor deposition process. STI layer 31 may include SiO₂. Fin 32 may include monocrystalline silicon. Dielectric layer 33 may include hafnium oxide (HfO₂). Dummy gate layer 34 is a dummy poly gate including polysilicon.

At 202: defining positions of a plurality of word lines on the dummy gate layer.

In one embodiment, referring to FIG. 3B, spacers 35 are formed on dummy gate layer 34 to define positions of the word lines. Spacers 35 may include silicon oxide or silicon nitride. It is noted that the number of spacers 35 may be determined according to actual requirements and is not limited to those shown in FIG. 3B.

At 203: defining positions of two select gates on opposite sides of the positions of the plurality of word lines on the dummy gate layer.

In one embodiment, referring to FIG. 3C, dummy gate layer 34 is patterned to form a densely packed unit 36 and first and second independent units 37. Densely packed unit 36 determines the positions of the word lines. First and second independent units 37 each determine the position of one of the select gates.

It is noted that the second independent unit (not shown) is disposed symmetrically with respect to first independent unit 37 on the other side of densely packed unit 36.

At 204: forming a source and a drain on the fin layer outside of the positions of the two select gates.

In one embodiment, referring to FIG. 3D, a source 38 is formed on fin layer 32 and adjacent first independent unit 37. Source 38 has an upper surface flush with the upper surface of dielectric layer 33. Source 38 may include phosphide or silicon carbide. A drain is disposed symmetrically with respect to source 38 on the other side of the densely packed unit 36 and adjacent to the second independent unit. The drain includes the same material as that of source 38.

At 205: forming two select gates and a plurality of word lines on the dummy gate layer.

In one embodiment, referring to FIG. 3E, a plurality of word lines 39 and first and second select gates 310 are formed in accordance with the positions of densely packed unit 36 and independent unit 37. Select gates 310 and word lines 39 each may include metal, such as titanium nitride or tungsten.

It is noted that the second select gate (not shown) is disposed symmetrically with respect to first select gate 310 on the other side of the plurality of word lines 39 and includes the same material as that of first select gate 310.

In another embodiment, a plurality of contacts are formed on the source and drain. Referring to FIG. 3F, a contact 311 is formed on source 38. A contact (not shown) is also formed on the drain (not shown).

In the embodiment, the source, drain and contacts are formed outside of the select gates of the semiconductor device. A plurality of word lines are formed between the select gates to form a NAND-type memory structure. In accordance to the embodiment of the present invention, the semiconductor device does not require a source, a drain and contacts to be formed on opposite sides of each select gate to provide the electron source. In accordance with the present invention, the semiconductor device utilizes electronic tunneling effects to inject electrons from the trenches of the fin layer to program the operations of the memory, thereby increasing the memory density and the speed of write and erase operations.

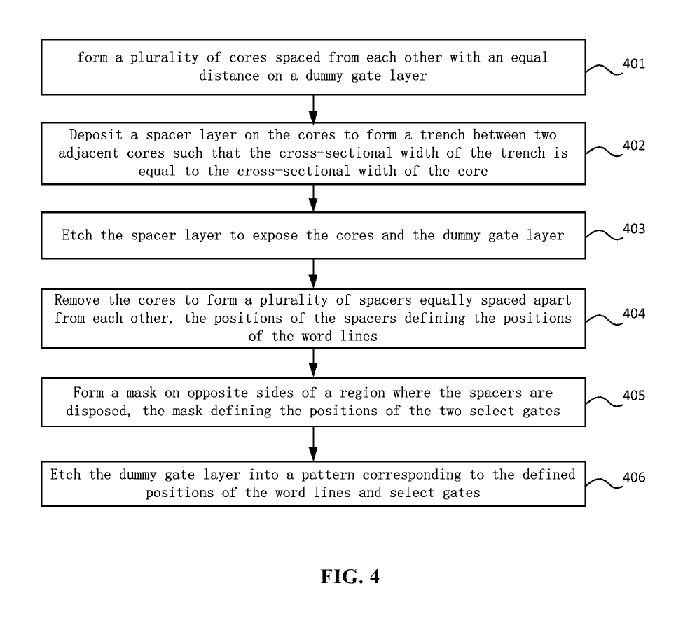

FIG. 4 is a simplified flowchart illustrating an example method of defining positions of the word lines and positions of select gates according to one embodiment of the present disclosure.

Referring to FIG. 4, the method include:

At 401: forming a plurality of cores spaced from each other with an equal distance on a dummy gate layer.

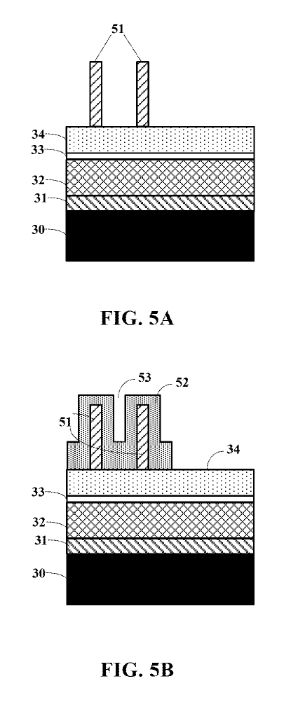

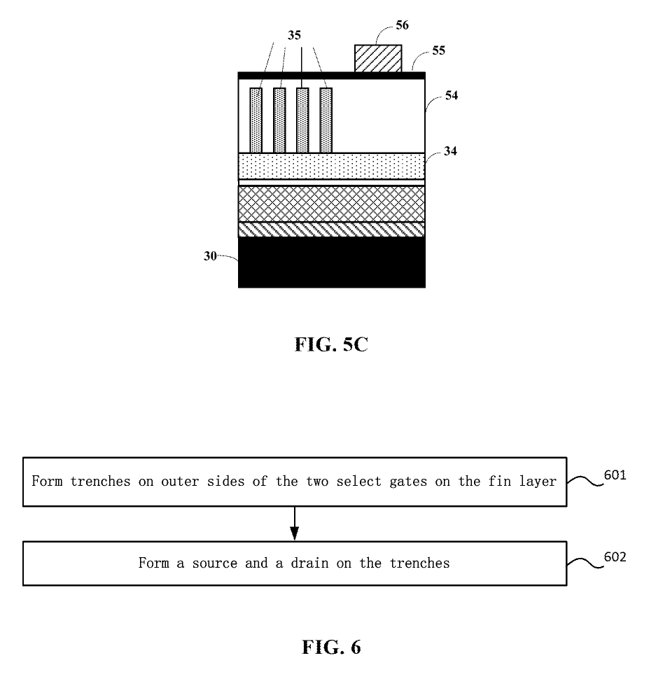

In one embodiment, referring to FIG. 5A, an amorphous carbon layer is formed on a dummy gate layer 34, and a stripe pattern with predetermined equal intervals is formed on the amorphous carbon layer using a photolithography and etching process. The amorphous carbon layer is then etched using the stripe pattern as a mask to form a plurality of equally spaced cores extending across the dummy gate layer. In one example embodiment, two cores 51 are formed by etching using the stripe pattern as a mask.

At 402: depositing a spacer layer on the cores to form a trench between two adjacent cores such that the cross-sectional width of the trench is equal to the cross-sectional width of the core.

In one embodiment, referring to FIG. 5B, a spacer layer 52 including silicon nitride or silicon oxide is grown using an atomic layer deposition process to form a trench 53 between adjacent cores 51, trench 53 has a cross-sectional width that is equal to the cross-sectional width of core 51.

At 403: etching the spacer layer to expose the cores and the dummy gate layer.

In one embodiment, a portion of isolation layer 52 above an upper surface of cores 51 and a portion of spacer layer 52 in trench 53 are etched to expose cores 51 and a portion of dummy gate layer 34.

At 404: removing the cores to form a plurality of spacers spaced apart from each other with an equal distance, the positions of the spacers defining the positions of the word lines.

In one embodiment, referring to FIG. 5C, cores 51 are removed to form the positions of four spacers 35 that are equally spaced apart from each other, the positions of four spacers define the positions of four word lines. It is understood that the number of trenches 53 and spacers 35 can be any integer number. In the example shown in FIG. 5C, four spacers are used to define the positions of the word lines. But it is understood that the number is arbitrary chosen for describing the example embodiment and should not be limiting. That is, the number of cores 51, the number of trenches 53, and the number of spacers 35 can be determined according to actual requirements.

At 405: forming a mask on opposite sides of a region where the spacers are disposed, the position of the mask defines the positions of the two select gates.

In one embodiment, referring to FIG. 5C, an organic insulating layer 54 is formed on dummy gate layer 34 by a spin-coating process, and a silicon-containing antireflection layer 55 is deposited on organic insulating layer 54. Thereafter, a photoresist 56 is formed on silicon-containing antireflection layer 55 and is used to determine the positions of the select gates.

At 406: etching the dummy gate layer into a pattern corresponding to the already defined positions of the word lines and the positions of the select gates.

Returning to FIG. 3C, dummy gate layer 34 is etched into a corresponding pattern according to the positions defined by spacers 35 and photoresist 56, where densely packed unit 36 and independent unit 37 respectively determine the positions of the word lines and the select gates on dummy gate layer 34. It is noted that only the position determining steps of densely packed unit 36 and the position of one select gate on one side of the densely packed unit are described in the embodiment. The position of the select gate on the opposite side of densely packed unit 36 can also be determined by referring to the above described steps and will be omitted herein for the sake of brevity.

In the above embodiment, a plurality of word lines are formed on the inner sides of the two select gates to form a NAND-type memory structure. Therefore, it is not required to form a source and a drain on opposite sides of each gate to provide an electron source. In accordance with the present disclosure, the operations of the memory can be performed by electron tunneling effects to injecting electrons in the channel of the fin layer, thereby increasing the memory density and the speed of write and erase operations.

FIG. 6 is a simplified flowchart illustrating an example method for forming a source and a drain of a semiconductor device according to one embodiment of the present disclosure.

Referring to FIG. 6, the method includes, at 601, forming trenches on the outer sides of the two select gates on the fin layer.

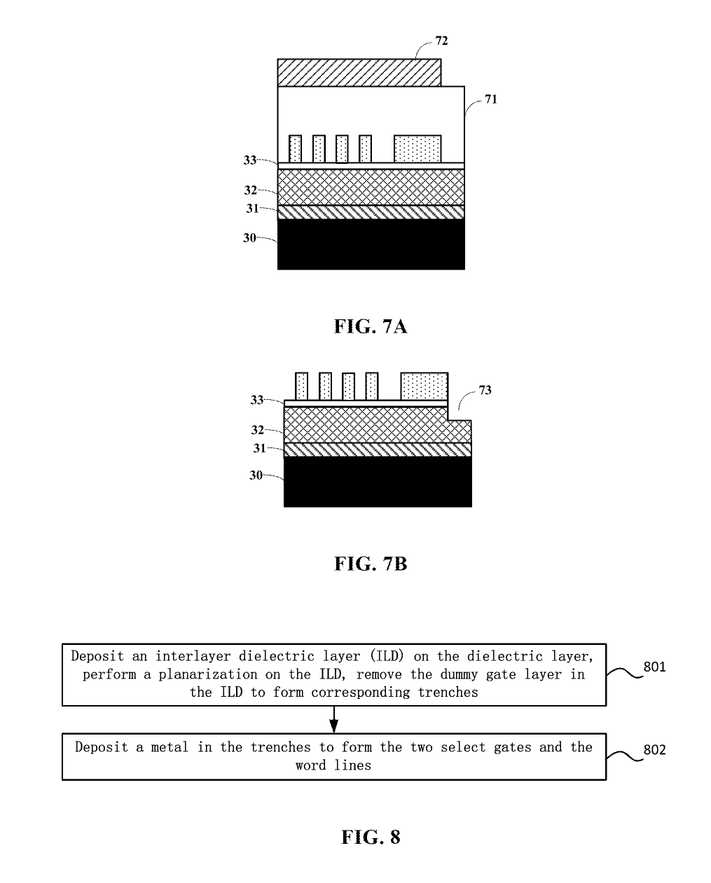

In one embodiment, referring to FIG. 7A, a bottom anti-reflective coating 71 is spin-coated on dielectric layer 33, and then a photoresist 72 is formed on bottom anti-reflective coating 71 as a mask. Photoresist 72 has a length that is less than the length of bottom anti-reflective coating 71. Photoresist 72, bottom anti-reflective coating 71, a portion of dielectric layer 33 and a portion of fin layer 32 are then etched to form a trench 73 adjacent to independent unit 37, as shown in FIG. 7B. It is noted that another trench 73 (not shown) is also formed symmetrically to first independent unit 37 on the other side of densely packed unit 36.

At 602: forming a source and a drain on the two trenches, respectively.

In one embodiment, referring to FIG. 3D, a phosphide or silicon carbide material is deposited on trench 73 to form a source 38 that has an upper surface that is flush with the upper surface of dielectric layer 33.

It is noted that the source forming step is described in the above-described embodiment. It is understood that the drain can be formed in the same manner as the formation of the source and will not be described herein.

In the above embodiment, a source and a drain are formed on the outside of the select gates disposed on opposite sides of the semiconductor device, and a plurality of word lines are formed on the inner sides of the two select gates to form a NAND-type memory structure. According to the present invention, a source and a drain are not required to be formed on opposite sides of each gate to provide the electron source. By utilizing the electron tunneling effect and by injecting electrons in the channel of the fin layer the memory device can be programmed, thereby improving the memory density and the speed of the write and erase operations.

FIG. 8 is a simplified flowchart illustrating an example method for forming select gates and word lines of a semiconductor device according to one embodiment of the present disclosure.

Referring to FIG. 8, the method includes, at 801, depositing an interlayer dielectric layer, and performing a planarization on the interlayer dielectric layer. Thereafter, the method includes removing the dummy gate layer disposed between the interlayer dielectric layer to form corresponding trenches.

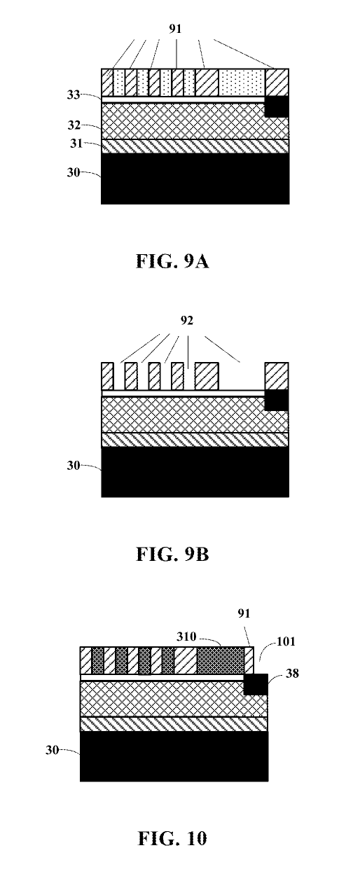

In one embodiment, referring to FIG. 9A, an interlayer dielectric layer 91 is deposited on dielectric layer 33 covering densely packed unit 36 and dependent units 37, a planarization (e.g., CMP) process is performed on the interlayer dielectric layer until a surface of densely packed unit 36 and dependent units 37 is exposed.

Referring to FIG. 9B, the method includes removing densely packed unit 36 and independent unit 37 between interlayer dielectric layer 91 to form corresponding trenches 92.

At 802: depositing a metal in the trenches to form the two select gates and the plurality of word lines.

In one embodiment, referring to FIG. 3E, tungsten or titanium nitride can be deposited in trenches 92 to form select gates 310 and word lines 39.

In another embodiment, referring to FIG. 10, a portion of interlayer dielectric layer 91 on the outside of select gates 310 and on source 38 is etched to form a recess 101 on source 38.

Returning to FIG. 3F, a contact 311 is formed in recess 101 on source 38.

It is to be noted that only the step of forming one select gate, the source and the contact on the source is described in the above embodiment. The other select gate, the drain, and the contact on the drain on the other side of the densely packed unit can be formed in the same manner referring to the above-described step and the description thereof is omitted herein for the sake of brevity.

In the above embodiment, by forming a NAND type memory structure, a source and a drain are not formed on opposite sides of each gate to provide an electron source, thereby improving the memory density and the speed of write and erase operations.

While the present disclosure is described herein with reference to illustrative embodiments, this description is not intended to be construed in a limiting sense. Rather, the purpose of the illustrative embodiments is to make the spirit of the present disclosure be better understood by those skilled in the art. In order not to obscure the scope of the disclosure, many details of well-known processes and manufacturing techniques are omitted. Various modifications of the illustrative embodiments as well as other embodiments will be apparent to those of skill in the art upon reference to the description. It is therefore intended that the appended claims encompass any such modifications.

What is claimed is:

1. A semiconductor device, comprising:
one or more bit lines;
first and second select gates on the one or more bit lines;
a plurality of word lines on the one or more bit lines and between the first and second select gates; and
a source and a plurality of drains on the one or more bit lines, wherein the source is disposed at an outside of the first select gate and the plurality of drains are disposed at an outside of the second select gate.

2. The semiconductor device of claim 1, wherein positions of two of the plurality of drains on two adjacent bit lines are shifted from each other along a direction of the one or more bit lines.

3. The semiconductor device of claim 2, further comprising contacts on the source, the drains, and on the first and second select gates.

4. A method for manufacturing a semiconductor device, the method comprising:
providing a substrate;
sequentially forming s shallow trench isolation (STI) layer, a fin layer, a dielectric layer, and a dummy gate layer on the substrate;
defining positions of a plurality of word lines on the dummy gate layer;
defining positions of first and second select gates on opposite sides of the plurality of word lines;
forming a source at an outside of the position of the first select gate and a drain at an outside of the position of the second select gate on the fin layer; and
forming first and second select gates on the positions of the first and second select gates and a plurality of word lines on the positions of the plurality of word lines on the dummy gate layer.

5. The method of claim 4, further comprising:
forming contacts on the source and the drain.

6. The method of claim 5, wherein:
the dummy gate layer comprises polysilicon;
the fin layer comprises monocrystalline silicon; and
the STI layer comprises SiO₂.

7. The method of claim 6, wherein defining the positions of the plurality of word lines on the dummy gate layer comprises:
forming a plurality of cores spaced from each other with an equal distance on the dummy gate layer and having a same cross-sectional width;
forming a spacer layer on the plurality of cores to from a trench between two adjacent cores, the trench having a cross-sectional width equal to the cross-sectional width of the cores;
etching the spacer layer to expose the cores and the dummy gate layer;
removing the cores to form a plurality of spacers spaced from each other with an equal distance, each of the plurality of spacers defining a position of the word lines.

8. The method of claim 7, wherein:
the cores comprise amorphous carbon; and
the spacer layer comprises silicon nitride or silicon oxide.

9. The method of claim 8, wherein defining the positions of the first and second select gates on opposite sides of the plurality of word lines comprises:
forming a mask on opposite sides of a region where the spacers are disposed, the mask being disposed at a position defining the positions of the first and second select gates;
etching the dummy gate layer into a pattern corresponding to the positions of the word lines and the first and second select gates.

10. The method of claim 4, wherein forming the source at the outside of the position of the first select gate and the drain at the outside of the position of the second select gate on the fin layer comprises:
forming trenches on outer sides of the positions of the first and second select gates on the fin layer;
forming the source and the drain on the respective trenches.

11. The method of claim 10, wherein the source and the drain each comprises silicon phosphide or silicon carbide, the source and the drain each having an upper surface that is flush with an upper surface of the dielectric layer.

12. The method of claim 4, wherein forming the first and second select gates and the plurality of word lines on the dummy gate layer comprises:
forming an interlayer dielectric layer on the dielectric layer;
planarizing the interlayer dielectric layer;
removing the dummy gate layer in the interlayer dielectric layer to form corresponding trenches;
forming a metal in the trenches to form the first and second select gates and the plurality of word lines.

13. A memory device comprising the semiconductor device of claim 1.
